(19) United States
(12) Patent Application Publication
(10) Pub. No.: US 2010/0051330 A1
(43) Pub. Date: Mar. 4, 2010

(54) WIRING BOARD AND DISPLAY UNIT

(75) Inventors: Kenichi Yamashita, Sakai-shi (JP); Yoshiki Nakatani, Nara-shi (JP); Akitsugu Hatano, Nara-shi (JP)

Correspondence Address: SHARP KABUSHIKI KAISHA;C/O KEATING & BENNETT, LLP, 1800 Alexander Bell Drive, SUITE 200, Reston, VA, 20191, US

(73) Assignee: SHARP KABUSHIKI KAISHA, Osaka-shi, Osaka (JP)

(21) Appl. No.: 12/447,977

(22) PCT Filed: Jul. 18, 2007
(86) PCT No.: PCT/JP2007/064195

§ 371 Date: Apr. 30, 2009

(30) Foreign Application Priority Data
Nov. 29, 2006 (JP) 2006-321665

(51) Int. Cl. H05K 1/03

(52) U.S. Cl. 174/255

(57) ABSTRACT

A wiring board formed by mounting an IC chip on a mounting substrate includes a resin substrate and a wiring pattern. The resin substrate includes having a reinforcing material obtained by impregnating glass fibers with a resin and an organic layer provided on a surface of the reinforcing material. The wiring pattern is disposed on a surface of the resin substrate through a coating layer. The IC chip includes a bump electrode for connection with the wiring pattern. The resin substrate includes a fiber exposure portion through which the reinforcing material is exposed, and the IC chip is fixed to the mounting substrate through an ACF adhered to the fiber exposure portion with the connection electrode being connected to the wiring pattern.

### BACKGROUND OF THE INVENTION

1. Field of the Invention

The present invention relates to a wiring board and a display unit, and specifically to the mounting technique of mounting an electronic component on a resin substrate through an anisotropic conductive film or the like.

2. Description of the Related Art

An anisotropic conductive film (hereinafter, referred to as “ACF”) is an adhesive film made of a thermosetting resin or the like in which conductive particles, such as plastic particles covered by a metal film or metal particles, are dispersed. Therefore, the ACF is widely used for electrically connecting an electronic component with a mounting substrate with the anisotropic conductivity and the adhesive property of the ACF being advantageously used (see, for example, Japanese Unexamined Patent Publication H09-244047).

A mounting method using a conventional ACF will be described below with reference to FIG. 17. It should be noted that FIG. 17 is a cross section of a mounting section of a conventional wiring board 130.

Here, a wiring board main body 120 is a mounting substrate including: a resin substrate 110 composed of a reinforcing material 105 made by a glass cloth impregnated with a resin and organic layers 106a and 106b respectively provided on an upper surface and a lower surface of the reinforcing material 105; inorganic films 111a and 111b respectively provided on an upper surface and a lower surface of the resin substrate 110; and wiring patterns 112 provided on an upper surface of the inorganic film 111a. An integrated circuit (hereinafter, referred to as “IC”) chip 115 is an electronic component including a chip main body 115a and a plurality of bump electrodes 115b provided on and projecting from a bottom surface of the chip main body 115a.

Now, to mount the IC chip 115 on the wiring board main body 120, first, an ACF 117 is pre-bonded to the wiring patterns 112 of the wiring board main body 120 by heating. Subsequently, the IC chip 115 is arranged on the ACF 117, and then the IC chip 115 is pressed from above and pressure is applied thereon. Further, the IC chip 115 and the ACF 117 are heated to post-bond the IC chip 115 to the wiring board main body 120. At this time, in the wiring board 130, due to the heating and the applying pressure, a resin component in the ACF 117 melts so as to flow out between the bump electrodes 115b and the wiring patterns 112, and a portion of conductive particles dispersed in the ACF 117 is held between the bump electrodes 115b and the wiring patterns 112. Thus, in the wiring board 130, the IC chip 115 is fixed to the wiring board main body 120 through the resin component in the ACF 117 with the conductive particles in the ACF 117 pressed between the bump electrodes 115b and the wiring patterns 112, thereby the bump electrodes 115b are electrically connected to the wiring patterns 112. After that, as shown in FIG. 17, an insulating resin 118 may be applied around the IC chip 115 as a countermeasure against vibration and impact or moisture resistance. It should be noted that in the same manner as the IC chip 115, an FPC 116 in FIG. 17 is mounted on the wiring board main body 120 through the ACF 117.

Now, in the case where electronic components, such as an IC chip and a flexible printed circuit (hereinafter, referred to as “FPC”), are mounted on a glass substrate through an ACF, the adhesive forces respectively between the IC chip and the ACF, between the FPC and the ACF, between a wiring pattern and the ACF, and between a glass substrate main body and the ACF may be reduced over time. Here, it is contemplated that the chip-on-glass (COG) adhesive strength and the FPC adhesive strength to the glass substrate largely depend respectively on the adhesive strength between the IC chip and the ACF and the adhesive strength between the FPC and the ACF.

Meanwhile, in the case where the IC chip 115 and the FPC 116 are mounted on the wiring board main body 120 made of resin through the ACF 117 as shown in FIG. 17, it is contemplated that the COG adhesive strength and the FPC adhesive strength are weaker as compared to the aforementioned case of mounting to the glass substrate, because the adhesive forces respectively between the inorganic film 111a and the resin substrate 110 and between the reinforcing material 105 and the organic layer 106a of the resin substrate 110 may become smaller than the adhesive forces respectively between the IC chip 115 and the ACF 117 and between the FPC 116 and the ACF 117 over time. Here, the wiring board main body 120 made of resin is generally more flexible than the glass substrate, and thus if the wiring board main body 120 made of resin bends with an inflexible IC chip 115 being mounted thereon, a local stress may be applied to ends, especially corners, of the IC chip 115. In this case, in the wiring board 130, the IC chip 115 may come off the wiring board main body 120.

### SUMMARY OF THE INVENTION

In view of the problems above, preferred embodiments of the present invention significantly improve the adherence of an electronic component which is to be mounted on a resin substrate containing a fibrous reinforcing material as compared to a conventional art.

According to a preferred embodiment of the present invention, a resin substrate constituting a mounting substrate includes a fiber exposure portion, and an electronic component is fixed to the mounting substrate through an adhesive layer adhered to the fiber exposure portion.

A wiring board specifically according to a preferred embodiment of the present invention is preferably formed by mounting an electronic component on a mounting substrate, the mounting substrate including a resin substrate having a fibrous reinforcing material and a wiring pattern provided on the resin substrate, the electronic component including a connection electrode for connection with the wiring pattern, wherein the resin substrate has a fiber exposure portion through which the reinforcing material is exposed, and the electronic component is fixed to the mounting substrate through an adhesive layer adhered to the fiber exposure portion with the connection electrode being electrically connected to the wiring pattern.

In this configuration, the electronic component is adhered through the adhesive layer to the fiber exposure portion of the resin substrate through which the fibrous reinforcing material is exposed, and thus the contact (adhesion) area between the resin substrate and the adhesive layer is larger as compared to the conventional case where the adhesive layer is adhered to other portions than the fiber exposure portion. Thus, the adherence between the resin substrate and the adhesive layer is greatly improved as compared to the conventional case, while the adherence between the adhesive layer and the electronic component is maintained as it is in the conventional case. Therefore, it is possible to further improve the adherence of the electronic component which is to be mounted on the resin substrate having the fibrous reinforcing material as compared to the conventional art.

The reinforcing material may be glass fibers impregnated with a resin. The resin substrate may include an organic layer provided on a surface of the reinforcing material. The organic layer may have an opening through which the reinforcing material is exposed.

In this configuration, the glass fibers are exposed through the fiber exposure portion where the organic layer has the opening, and thus the contact (adhesion) area between the resin substrate and the adhesive layer is larger as compared to the conventional case where the adhesive layer is adhered to a surface of the organic layer. Therefore, advantages, functions and effects of preferred embodiments of the present invention are specifically achieved.

Between the resin substrate and the wiring pattern, a coating layer may be provided, and the coating layer may have an opening through which the reinforcing material is exposed.

In this configuration, the fibrous reinforcing material is exposed through the fiber exposure portion where the coating layer has the opening, and thus the contact (adhesion) area between the resin substrate and the adhesive layer is larger as compared to the conventional case where the adhesive layer is adhered to a surface of the coating layer. Therefore, advantages, functions and effects of preferred embodiments of the present invention are specifically achieved.

The electronic component may be an integrated circuit chip, for example.

In this configuration, the integrated circuit chip is adhered through the adhesive layer to the fiber exposure portion of the resin substrate through which the fibrous reinforcing material is exposed. Therefore, when the integrated circuit chip is mounted on the resin substrate, advantages, functions and effects of preferred embodiments of the present invention are specifically achieved.

The integrated circuit chip may have flexibility, for example.

In this configuration, for example, as compared to a conventional integrated circuit chip having a thickness of about 400 μm, forming the integrated circuit chip to have a thickness of about 200 μm for providing the integrated circuit chip with flexibility enables the integrated circuit chip to be deformed along with a bending of the mounting substrate made of resin. Therefore, it is possible to further improve the adherence of the integrated circuit chip which is to be mounted on the resin substrate.

The integrated circuit chip may have arc-shaped corners when viewed in plan, for example.

In this configuration, the integrated circuit chip has the arc-shaped corners when viewed in plan, and thus the stress applied to the comers of the integrated circuit chip when the mounting substrate bends is dispersed. Therefore, it is possible to further improve the adherence of the integrated circuit chip which is to be mounted on the resin substrate.

The integrated circuit chip may have a sidewall fixed to the mounting substrate through the resin layer adhered to the fiber exposure portion.

In this configuration, the sidewall of the integrated circuit chip is fixed to the mounting substrate through the resin layer adhered to the fiber exposure portion. Therefore, a countermeasure against vibration and impact or moisture resistance of the integrated circuit chip becomes more effective.

The adhesive layer may be formed by an anisotropic conductive film, for example.

In this configuration, the electronic component is adhered through the anisotropic conductive film to the fiber exposure portion of the resin substrate through which the fibrous reinforcing material is exposed, and thus the connection electrode of the electronic component and the wiring pattern of the mounting substrate are electrically connected through conductive particles in the anisotropic conductive film. Therefore, advantages, functions and effects of preferred embodiments of the present invention are specifically achieved.

Moreover, a display unit according to a preferred embodiment of the present invention is preferably formed by mounting an electronic component on a display panel provided with a mounting substrate, the mounting substrate including a resin substrate having a fibrous reinforcing material and a wiring pattern provided on a surface of the resin substrate, the electronic component including a connection electrode for connection with the wiring pattern, wherein the resin substrate has a fiber exposure portion through which the reinforcing material is exposed, and the electronic component is fixed to the mounting substrate through an adhesive layer adhered to the fiber exposure portion with the connection electrode being electrically connected to the wiring pattern.

In this configuration, in the mounting substrate (for example, an active matrix substrate) constituting the display panel, the electronic component is adhered through the adhesive layer to the fiber exposure portion of the resin substrate through which the fibrous reinforcing material is exposed, and thus the contact (adhesion) area between the resin substrate and the adhesive layer is larger as compared to the conventional case where the adhesive layer is adhered to other portions than the fiber exposure portion. Thus, the adherence between the resin substrate and the adhesive layer is greatly improved as compared to the conventional case, while the adherence between the adhesive layer and the electronic component is maintained as it is in the conventional case. Therefore, in the display unit (for example, a liquid crystal display unit having the active matrix substrate), the adherence of the electronic component which is to be mounted on the resin substrate having the fibrous reinforcing material can be significantly improved as compared to the conventional art.

According to a preferred embodiment of the present invention, a resin substrate constituting a mounting substrate includes a fiber exposure portion, and an electronic component is fixed to the mounting substrate through an adhesive layer adhered to the fiber exposure portion. Therefore, it is possible to further improve the adherence of the electronic component which is to be mounted on the resin substrate having fibrous reinforcing material as compared to the conventional art.

Other features, elements, arrangements, steps, characteristics and advantages of the present invention will become more apparent from the following detailed description of preferred embodiments of the present invention with reference to the attached drawings.

### BRIEF DESCRIPTION OF THE DRAWINGS

FIG. 1 is a cross section of a mounting section of a wiring board 30a according to Preferred Embodiment 1 of the present invention.

FIG. 2 is a plan view of a mounting section of a liquid crystal display unit 60a according to Preferred Embodiment 1 of the present invention.

FIG. 3 is a cross section of the mounting section of the liquid crystal display unit 60a.

FIG. 4 is a plan view of a chip mounting section of an active matrix substrate 20a constituting the liquid crystal display unit 60a.

FIG. 5 is a plan view of a chip mounting section of an active matrix substrate 20b which is a variation of the active matrix substrate 20a.

FIG. 6 is a plan view of a chip mounting section of an active matrix substrate 20c which is a variation of the active matrix substrate 20a.

FIG. 7 is a plan view of a chip mounting section of an active matrix substrate 20d which is a variation of the active matrix substrate 20a.

FIG. 8 is a plan view of an FPC mounting section of the active matrix substrate 20a.

FIG. 9 is a plan view of an FPC mounting section of an active matrix substrate 20e which is a variation of the active matrix substrate 20a.

FIG. 10 is a plan view of an FPC mounting section of an active matrix substrate 20f which is a variation of the active matrix substrate 20a.

FIG. 11 is a plan view of a mounting section of the active matrix substrate 20a having a resin layer 18 formed to cover an IC chip 15.

FIG. 12 is a cross section of a chip mounting section of a wiring board 30b according to Preferred Embodiment 2 of the present invention.

FIG. 13 is a cross section of the chip mounting section of the wiring board 30b in a bending state.

FIG. 14 is a plan view of a chip mounting section of a wiring board 30c according to Preferred Embodiment 3 of the present invention.

FIG. 15 is a plan view of a mounting section of a liquid crystal display unit 60b according to Preferred Embodiment 4 of the present invention.

FIG. 16 is a cross section of the mounting section of the liquid crystal display unit 60b.

FIG. 17 is a cross section of a mounting section of a conventional wiring board 130.

FIG. 18 is a cross section of a chip mounting section of the wiring board 130.

FIG. 19 is a cross section of the chip mounting section of the wiring board 130 in a winding state.

FIG. 20 is a plan view of the chip mounting section of the wiring board 130.

### DETAILED DESCRIPTION OF THE PREFERRED EMBODIMENTS

Hereinafter, preferred embodiments of the present invention will be described in detail with reference to the drawings. It should be noted that the present invention is not limited to the preferred embodiments below.

### Preferred Embodiment 1 of the Present Invention

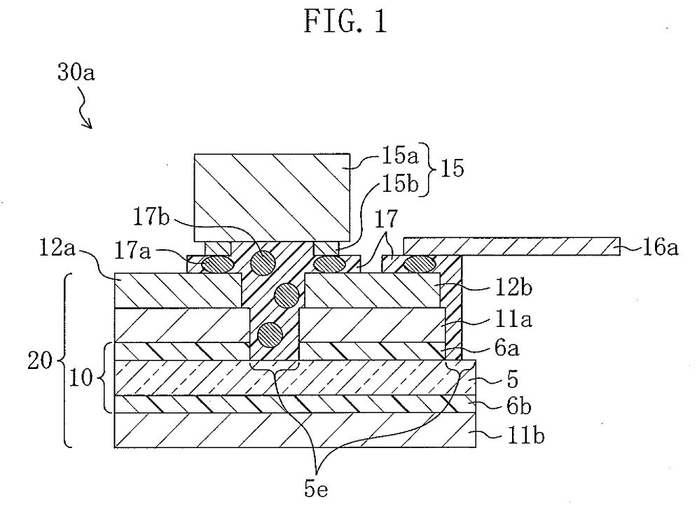

FIGS. 1 through 12 show Preferred Embodiment 1 of a wiring board and a display unit according to the present invention. It should be noted that in the present preferred embodiment, as the wiring board and display unit, a liquid crystal display unit in an active matrix drive system will be described as an example. Here, FIG. 1 is a cross section of a mounting section of a wiring board 30a according to the present preferred embodiment.

As shown in FIG. 1, the wiring board 30a includes a wiring board main body 20, and an IC chip 15 and an FPC 16a each mounted on a mounting section of the wiring board main body 20 through an ACF 17.

As shown in FIG. 1, the wiring board main body 20 is a mounting substrate including a resin substrate 10, coating layers 11a and 11b respectively provided on an upper surface and a lower surface of the resin substrate 10, and wiring patterns 12a and 12b provided on an upper surface of the coating layer 11a.

As shown in FIG. 1, the resin substrate 10 includes a reinforcing material 5 obtained by weaving bundles of glass fibers in a lattice pattern into a glass cloth and then impregnating the glass cloth with a resin, and organic layers 6a and 6b respectively provided on an upper surface and a lower surface of the reinforcing material 5. It should be noted that the reinforcing material 5 may be made of the glass fibers as mentioned above, or may be made of aramid fibers, or the like.

Here, the organic layer 6a and the coating layer 11a have openings through which a portion of a surface of the reinforcing material 5 is exposed. Thus, the resin substrate 10 has fiber exposure portions 5e formed by the portion of the reinforcing material 5 exposed through the organic layer 6a and the coating layer 11a.

The IC chip 15 is an electronic component including a chip main body 15a, and a plurality of bump electrodes 15b provided on and projecting from a bottom surface of the chip main body 15a.

The FPC 16a is a film-like wiring board having routing wiring formed by, for example, a copper foil on a film base material made of a polyimide resin or the like. The ACF 17 is, for example, an adhesive film obtained by dispersing conductive particles 17a and 17b in a thermosetting epoxy resin or the like, wherein the conductive particles 17a and 17b are formed by plating plastic beads sequentially with nickel and gold as stacked layers on their surfaces. Although the present preferred embodiment refers to the ACF17 as an example of an adhesive layer adhered to the fiber exposure portions 5e, examples of the adhesive layer may include anisotropic conductive paste (ACP), non conductive film (NCF), non conductive paste (NCP), and conductive paste such as solder cream.

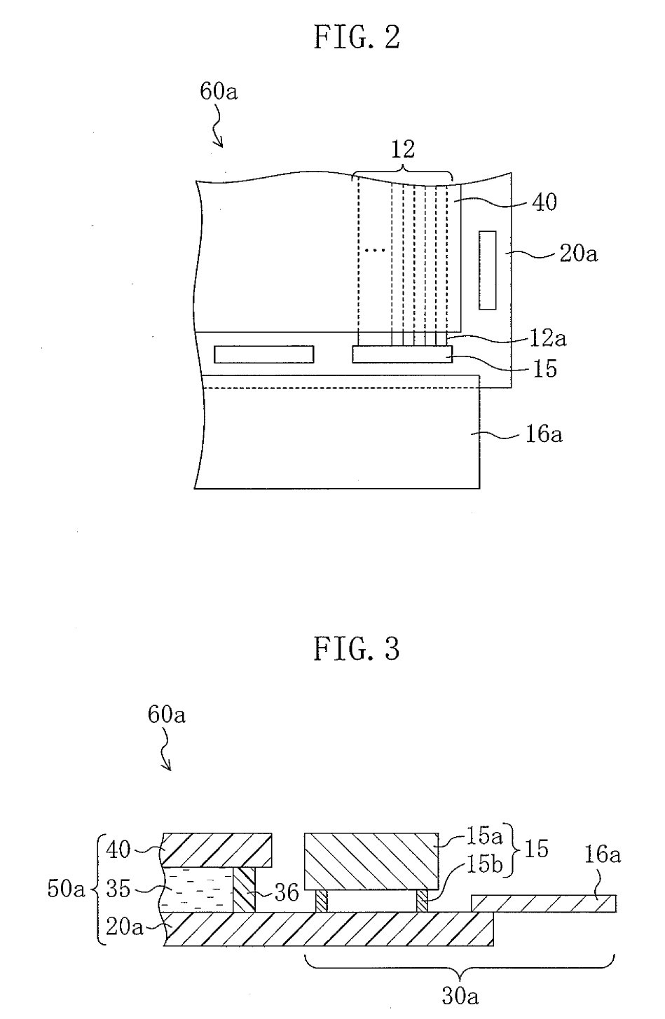

Moreover, as shown in FIG. 3, the wiring board 30a may form a liquid crystal display unit 60a. Here, FIG. 2 is a plan view of a mounting section of the liquid crystal display unit 60a, and FIG. 3 is a cross section of the mounting section of the liquid crystal display unit 60a.

As shown in FIG. 3, the liquid crystal display unit 60a includes a liquid crystal display panel 50a, an IC chip 15, and an FPC 16a. The liquid crystal display panel 50a has an active matrix substrate 20a corresponding to the aforementioned wiring board main body (mounting substrate) 20, a counter substrate 40 arranged to face the active matrix substrate 20a, and a liquid crystal layer 35 provided between the active matrix substrate 20a and the counter substrate 40. The IC chip 15 and the FPC 16a are each mounted on a mounting section of the liquid crystal display panel 50a through an ACF 17.

The active matrix substrate 20a preferably includes: a resin substrate 10; a plurality of gate lines 12 provided over the resin substrate 10 to extend parallel or substantially parallel to each other; a plurality of source lines (not shown) provided to extend parallel or substantially parallel to each other in a direction perpendicular or substantially perpendicular to the gate lines 12; a plurality of thin film transistors (hereinafter, referred to as “TFT”; not shown) respectively provided at intersections of the gate lines 12 and the source lines; and a plurality of pixel electrodes (not shown) respectively provided for the TFTs (see FIGS. 1 and 2). Here, the wiring pattern 12a of the wiring board 30a of FIG. 1 is, for example, an input terminal section at an end of a corresponding one of the gate lines 12. It should be noted that the wiring pattern 12a may be an input terminal section at an end of a line for display, e.g., a corresponding one of the source lines.

Moreover, in the active matrix substrate 20, a display region is formed by arranging pixels in matrix, wherein each pixel, i.e., the smallest unit of an image, is formed by each pixel electrode. Then, in an outer periphery section of the display region of the active matrix substrate 20a, a frame-shaped sealing section 36 is arranged to adhere to the counter substrate 40 and to surround the liquid crystal layer 35.

The counter substrate 40 includes a color filter layer (not shown) provided on a resin substrate (not shown), an overcoat layer (not shown) provided on the color filter layer, and a common electrode (not shown) provided on the overcoat layer. Here, the color filter layer includes a plurality of colored layers (not shown) each colored in red, green, or blue respectively corresponding to each pixel electrode on the active matrix substrate 20a, and a black matrix (not shown) provided between the colored layers.

The liquid crystal layer 35 is formed by, for example, nematic liquid crystals having electro-optical properties.

As shown in FIG. 2, in the liquid crystal display panel 50a, ends of, for example, two sides of the active matrix substrate 20a are arranged to project beyond the counter substrate 40, and the IC chip 15 and the FPC 16a for driving the panel are mounted on the projecting sections (a chip mounting section and an FPC mounting section which will be described later) of the active matrix substrate 20a.

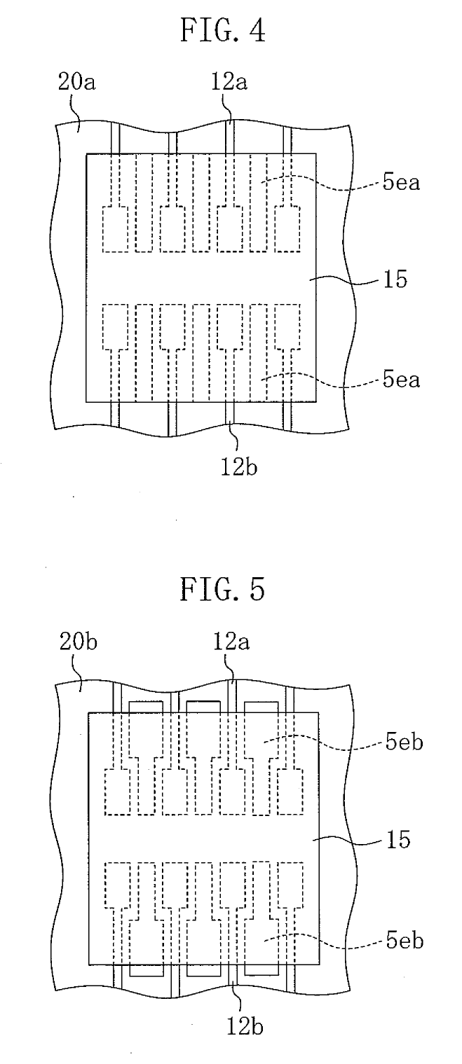

Here, as shown in FIG. 4, the chip mounting section of the active matrix substrate 20a is provided with a plurality of wiring patterns 12a, a plurality of wiring patterns 12b, and fiber exposure portions 5ea. The wiring patterns 12a extend in a longitudinal direction in an upper part of the figure and are connected to lines for display, e.g., the gate lines 12. The wiring patterns 12b extend in a longitudinal direction in a lower portion of the figure and are for connection with the FPC 16a. The fiber exposure portions 5ea extend between the wiring patterns 12a and between the wiring patterns 12b and correspond to the fiber exposure portions 5e of FIG. 1. It should be noted that the wiring patterns 12a and 12b each have a wide section for electrical connection with each bump electrode 15b of the IC chip 15.

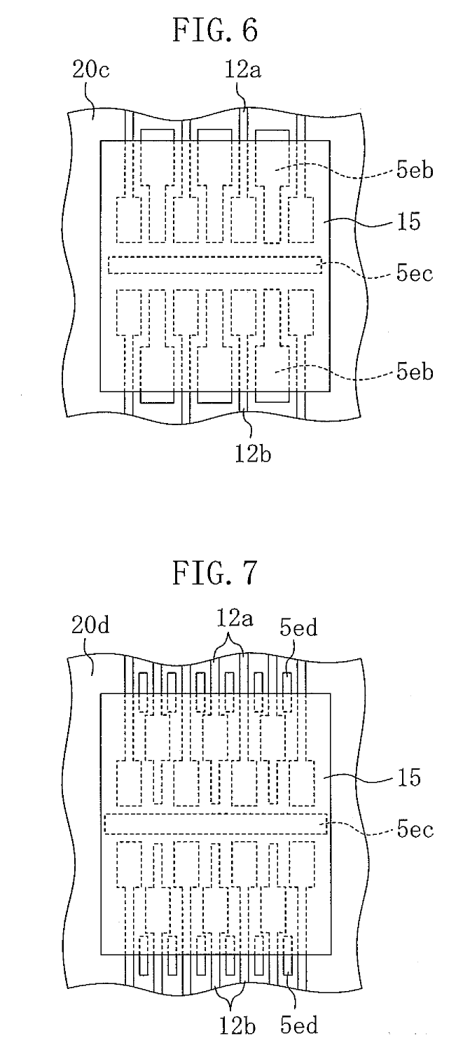

In addition to the fiber exposure portions described above, examples of the fiber exposure portions 5e of the chip mounting section may include, to allow the resin forming the ACF 17 to flow outside the IC chip 15 and to be solidified, fiber exposure portions formed to extend outward largely beyond the peripheral end of the IC chip 15 (see reference numeral 5eb of an active matrix substrate 20b of FIG. 5 and an active matrix substrate 20c of FIG. 6), fiber exposure portions formed to extend in a lateral direction in the figure between a group of wiring patterns 12a and a group of wiring patterns 12b (see reference numeral 5ec of the active matrix substrate 20c of FIG. 6 and an active matrix substrate 20d of FIG. 7), and fiber exposure portions narrowly formed outward between wiring patterns 12a and between wiring patterns 12b (reference numeral 5ed of an active matrix substrate 20d of FIG. 7) in the case of staggered arrangement of the bump electrodes 15b of the IC chip 15.

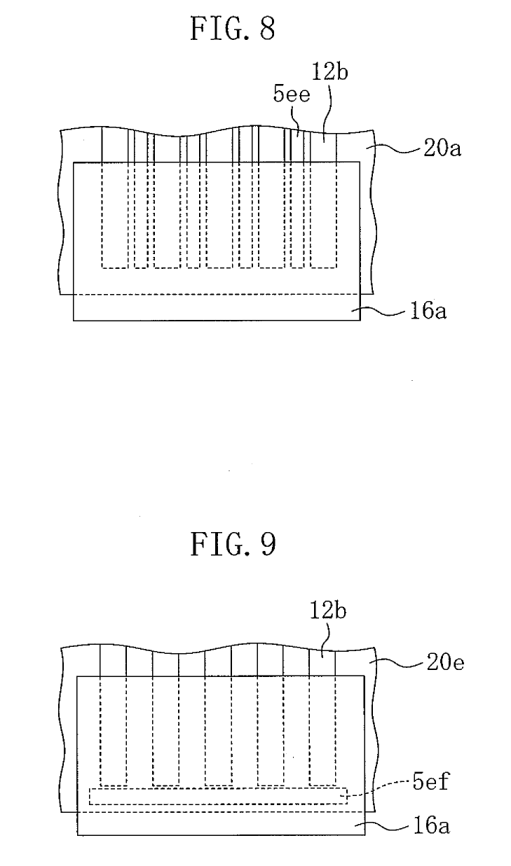

Moreover, as shown in FIG. 8, the FPC mounting section of the active matrix substrate 20a is provided with the plurality of wiring patterns 12b extending from the chip mounting section and fiber exposure portions 5ee extending between the wiring patterns 12b.

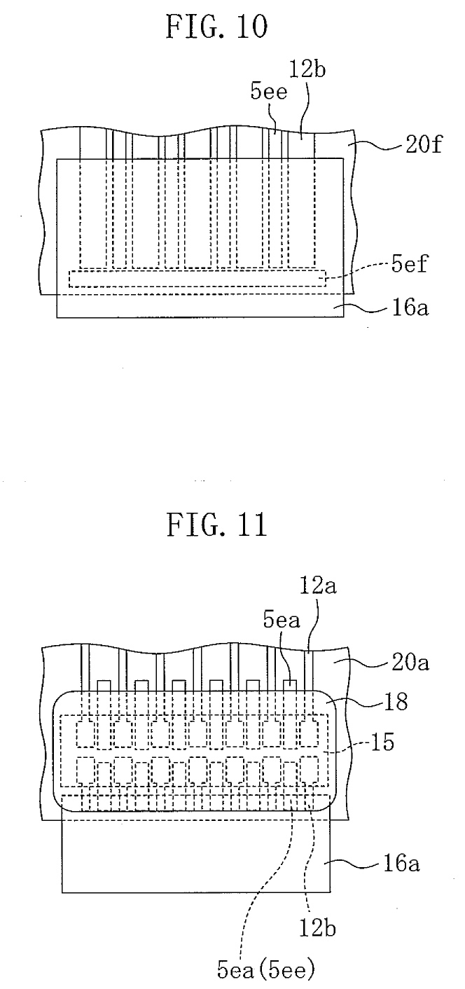

In addition to the above-described fiber exposure portions of the FPC mounting section, examples of the fiber exposure portions 5e of the FPC mounting section may include fiber exposure portions formed to extend in a lateral direction in the figure (see reference numeral 5ef of an active matrix substrate 20e of FIG. 9 and an active matrix substrate 20f of FIG. 10).

Moreover, as shown in FIG. 11, the mounting section of the active matrix substrate 20a may be provided with a resin layer 18 arranged to cover the IC chip 15. Here, in the same manner as the ACF 17, the resin layer 18 is adhered to the fiber exposure portions 5ea. Thus, sidewalls around the IC chip 15 are fixed to the active matrix substrate 20a through the resin layer 18 adhered to the fiber exposure portions 5ea. Therefore, it is possible to make a countermeasure against vibration and impact or moisture resistance more effective.

The liquid crystal display unit 60a described above is configured such that in each pixel, when the TFT is brought into an on state by a gate signal sent through the gate line 12, a source signal is sent through the source line to write a predetermined electric charge to a pixel electrode via the TFT in the on state, which causes a potential difference between the pixel electrode and the common electrode, thereby a predetermined voltage is applied to a liquid crystal capacitor formed by the liquid crystal layer 35. In the liquid crystal display unit 60a, by using the fact that an alignment state of liquid crystal molecules changes depending on the level of its applied voltage, the transmittance of incident light from a backlight unit (not shown) is adjusted, thereby an image is displayed.

Next, a method for mounting an IC chip 15 and an FPC 16a on a wiring board main body 20 through an ACF 17 will be described with reference to FIG. 1.

First, a glass cloth is impregnated with an epoxy resin, a phenolic resin, or the like to produce a reinforcing material 5. Then, to improve the smoothness or the gas barrier property of a substrate, a front surface and a back surface of the reinforcing material 5 are coated with a silicone-based or acrylate-based resin to form an organic layer formation film (6a) and an organic layer 6b, thereby a resin substrate base material is prepared.

Subsequently, on a front surface and a back surface of the resin substrate base material, a coating layer formation film (11a) and a coating layer 11b which are, for example, silicon oxide films are formed by plasma chemical vapor deposition (CVD).

Further, on a surface of the coating layer formation film, a metal conductive film which is, for example, a titanium film is formed by sputtering, and then pattern formation is performed by photolithography to form wiring patterns 12a and 12b. It should be noted that in the case where the wiring board main body 20 is an active matrix substrate, a TFT, a pixel electrode, and the like are subsequently formed.

After that, a predetermined region of the coating layer formation film is etched to form a coating layer 11a.

Further, the organic layer formation film exposed through the coating layer 11a is subjected to ashing by oxygen plasma or the like to form an organic layer 6a, thereby a fiber exposure portions 5e are formed.

In this way, the wiring board main body 20 can preferably be prepared.

Subsequently, onto the wiring patterns 12a and 12b of the wiring board main body 20, the ACF 17 is pre-bonded with the ACF 17 being heated to a temperature of about 80° C., for example.

Further, the IC chip 15 and the FPC 16a are arranged above the ACF 17, and then positioning is performed such that bump electrodes 15b of the IC chip 15 are above the wiring patterns 12a and 12b and (routing wiring of) the FPC 16a is above the wiring pattern 12b.

After that, using a bonding tool heated to a temperature of about 190° C., for example, the IC chip 15 and the FPC 16a are pressed from above and pressure is applied thereon, thereby post-bonding is achieved. At this time, between the wiring board main body 20 and the IC chip 15, due to the heating and the applying pressure, a resin component in the ACF 17 melts to flow out between (i) the bump electrodes 15b and (ii) the wiring patterns 12a and 12b, and between (i) the FPC 16a and (ii) the wiring pattern 12b, while conductive particles 17a dispersed in the ACF 17 are held between (i) the bump electrodes 15b and the FPC 16a and (ii) the wiring patterns 12a and 12b. Therefore, the conductive particles 17a in the ACF 17 are pressed between (i) the bump electrodes 15b (and the routing wiring of the FPC 16a) and (ii) the wiring patterns 12a and 12b, and thus the IC chip 15 and the FPC 16a are fixed to the wiring board main body 20 through the resin component in the ACF 17 with the bump electrodes 15b (and the routing wiring of the FPC 16a) and the wiring patterns 12a and 12b being electrically connected through the conductive particle 17a.

In this way, it is possible to fabricate a wiring board 30a on which the IC chip 15 and the FPC 16a are mounted.

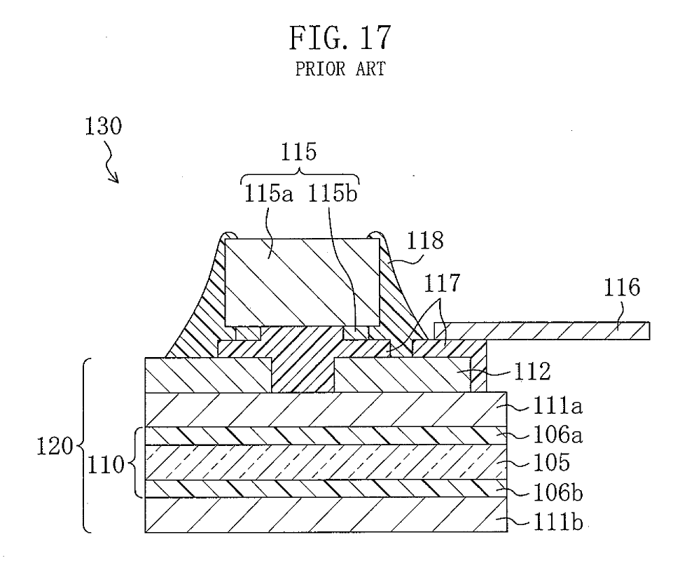

As described above, according to the wiring board 30a and the liquid crystal display unit 60a of the present preferred embodiment, in the wiring board main body 20 and the active matrix substrate 20a constituting the liquid crystal display panel 50a, the IC chip 15 and the FPC 16a are adhered through the ACF 17 to the fiber exposure portions 5e (5ea to 5ef) of the resin substrate 10 through which glass fibers of the reinforcing material 5 are exposed. Thus, the contact (adhesion) area between the resin substrate 10 and the ACF 17 is greater as compared to the conventional case where the ACF 117 is adhered to other portions than the fiber exposure portions (see FIG. 17). This further improves the adherence between the resin substrate 10 and the ACF 17 as compared to the conventional case, while the adherence between (i) the ACF 17 and (ii) the IC chip 15 and the FPC 16a is maintained as it is in a conventional case. Therefore, in the wiring board 30a and the liquid crystal display unit 60a, the adherence of the IC chip 15 and the FPC 16a which are to be mounted on the resin substrate 10 having the fiber-type reinforcing material 5 can be further improved as compared to the conventional case.

### Preferred Embodiment 2 of the Present Invention

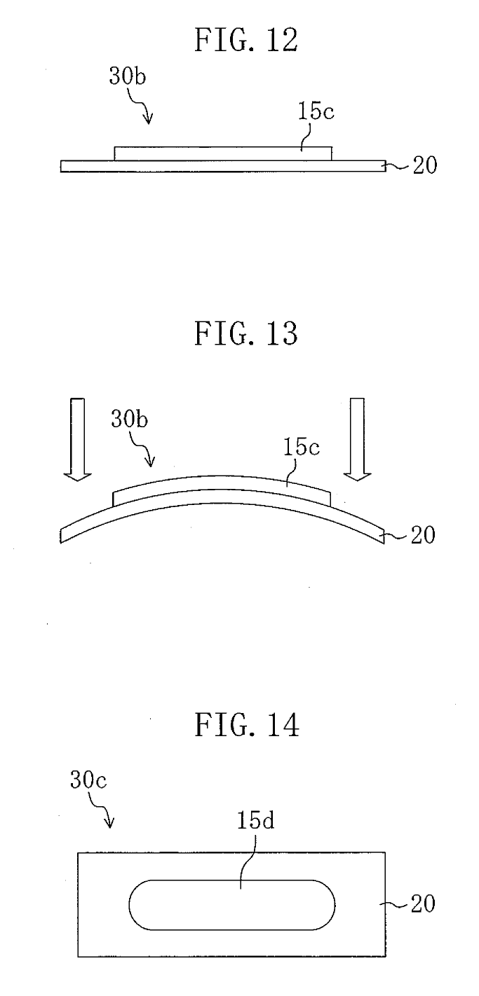

FIGS. 12 and 13 are cross sections of a chip mounting section of a wiring board 30b according to the present preferred embodiment. It should be noted that in preferred embodiments below, components which are the same as those in FIGS. 1 through 11 are denoted by the same reference numerals and detailed descriptions thereof are omitted.

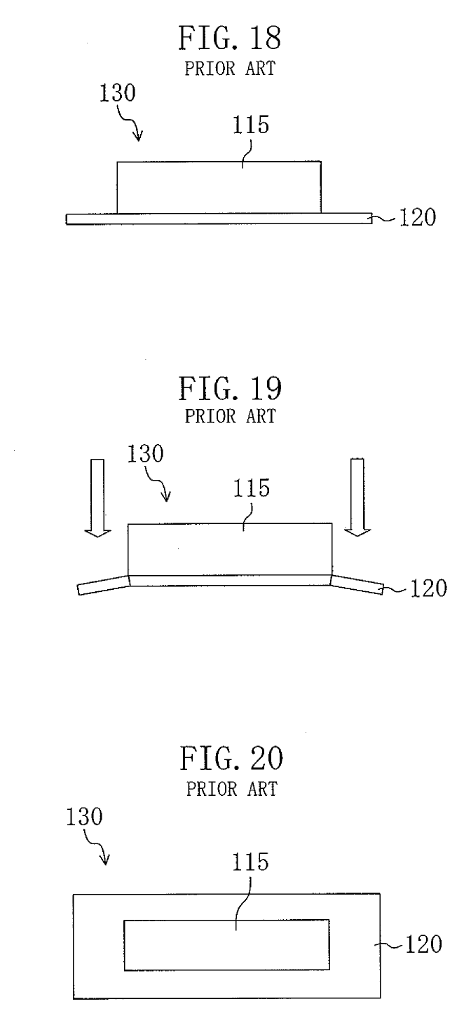

In Preferred Embodiment 1, the IC chip 15 preferably has a thickness of about 400 μm, whereas in the present embodiment, an IC chip 15c has a thickness of about 200 μm and flexibility, for example. This allows the IC chip 15c to deform along with a bend of a wiring board main body 20 made of resin, and thus it is possible to further improve the adherence of the IC chip 15c which is to be mounted on a resin substrate 10. By contrast, in a conventional wiring board 130 shown in FIGS. 18 and 19, if a wiring board main body 120 bends with an inflexible IC chip 115 being mounted thereon, a local stress may be applied on ends of the IC chip 115. In that case, in the wiring board 130, the IC chip 115 may come off the wiring board main body 120.

### Preferred Embodiment 3 of the Present Invention

FIG. 14 is a plan view of a chip mounting section of a wiring board 30c according to the present preferred embodiment.

In the wiring boards of Preferred Embodiments 1 and 2 and the conventional wiring board, the IC chip 15 and the IC chip 115 (see FIG. 20) have substantially right-angled corners, whereas in the present preferred embodiment, an IC chip 15d has arc-shaped corners (for example, in the case of an IC chip of 2 mm long and 10 mm width, the radius of curvature of the arc shape is about 0.8 mm) when viewed in plan. Therefore, the stress applied to the corners of the integrated circuit chip when a wiring board main body 20 bends is dispersed, and thus it is possible to further improve the adherence of the IC chip 15d which is to be mounted on a resin substrate 10.

### Preferred Embodiment 4 of the Present Invention

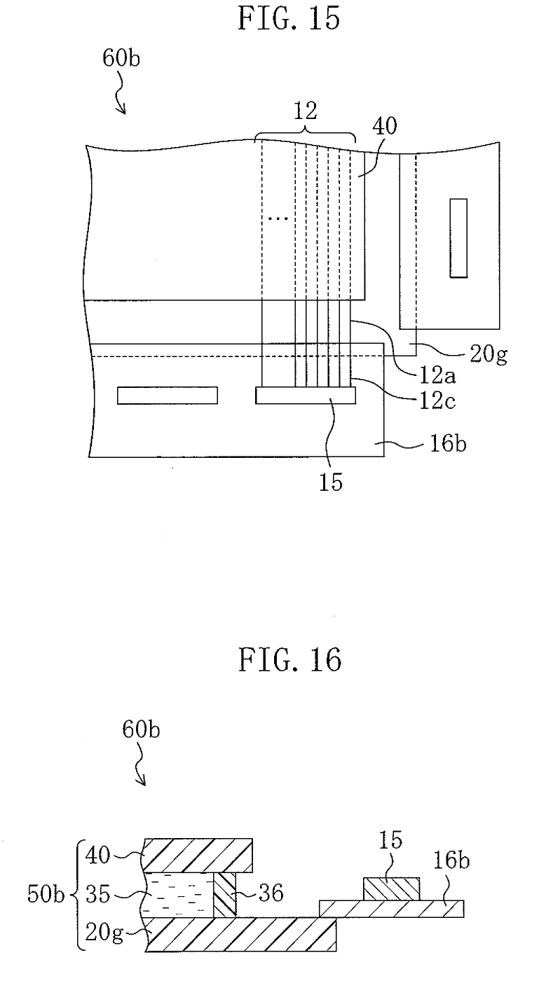

FIG. 15 is a plan view of a chip mounting section of a liquid crystal display unit 60b according to the present preferred embodiment, and FIG. 16 is a cross section of the chip mounting section of the liquid crystal display unit 60b.

In the liquid crystal display unit 60b, tape automated bondings (TABs) are mounted on ends of two sides of an active matrix substrate 20g. These TABs are circuit elements each obtained by mounting an IC chip 15 on an FPC 16b corresponding to the FPC 16a of Embodiment 1, and are adhered through an ACF 17 to fiber exposure portions 5e of a resin substrate 10 constituting the active matrix substrate 20g in the same manner as in the aforementioned preferred embodiments.

In the aforementioned preferred embodiments, a liquid crystal display unit in an active matrix drive system is taken as an example. However, various preferred embodiments of the present invention are applicable to display units such as a liquid crystal display unit in a passive matrix drive system and an EL (electroluminescence) display unit, and various wiring boards constituting electronic equipment.

As described above, preferred embodiments of the present invention greatly improve the adherence of an electronic component which is to be mounted on a resin substrate, and thus is useful for flexible wiring boards and flexible display units.

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-9. (canceled)

10. A wiring board comprising:
a mounting substrate arranged to mount an electronic component and including a resin substrate having a fibrous reinforcing material and a wiring pattern provided on the resin substrate, the electronic component including a connection electrode for connection with the wiring pattern; wherein
the resin substrate includes a fiber exposure portion through which the reinforcing material is exposed; and
the electronic component is fixed to the mounting substrate through an adhesive layer adhered to the fiber exposure portion with the connection electrode being electrically connected to the wiring pattern.

11. The wiring board of claim 10, wherein the reinforcing material includes glass fibers impregnated with a resin, the resin substrate includes an organic layer provided on a surface of the reinforcing material, and the organic layer has an opening through which the reinforcing material is exposed.

12. The wiring board of claim 10, further comprising a coating layer provided between the resin substrate and the wiring pattern, wherein the coating layer has an opening through which the reinforcing material is exposed.

13. The wiring board of claim 10, wherein the electronic component is an integrated circuit chip.

14. The wiring board of claim 13, wherein the integrated circuit chip has flexibility.

15. The wiring board of claim 13, wherein the integrated circuit chip has arc-shaped corners when viewed in plan.

16. The wiring board of claim 13, wherein the integrated circuit chip has a sidewall fixed to the mounting substrate through a resin layer adhered to the fiber exposure portion.

17. The wiring board of claim 10, wherein the adhesive layer includes an anisotropic conductive film.

18. A display unit comprising:
an electronic component;
a mounting substrate mounting the electronic component and including a resin substrate including a fibrous reinforcing material and a wiring pattern provided on a surface of the resin substrate, the electronic component including a connection electrode for connection with the wiring pattern; wherein
the resin substrate includes a fiber exposure portion through which the reinforcing material is exposed; and
the electronic component is fixed to the mounting substrate through an adhesive layer adhering to the fiber exposure portion with the connection electrode being electrically connected to the wiring pattern.
